(19) United States
(12) Patent Application Publication
(10) Pub. No.: US 2026/0110726 A1
(43) Pub. Date: Apr. 23, 2026

(54) Device and Method SSR Leakage Detection

(71) Applicant: Microchip Technology Inc., Chandler, AZ (US)

(72) Inventor: Andrei Bucsa, Gilbert, AZ (US)

(73) Assignee: Microchip Technology Inc., Chandler, AZ (US)

(21) Appl. No.: 19/197,194

(22) Filed: May 2, 2025

Related U.S. Application Data
(60) Provisional application No. 63/710,151, filed on Oct. 22, 2024.

(51) Int. Cl. G01R 31/26

(52) U.S. Cl. CPC G01R 31/2621

(57) ABSTRACT

A device is provided comprising a first and a second field effect transistor (FET), each having a source, a drain, and a gate, wherein the source of the first FET and the source of the second FET are both electrically connected to ground; a first leakage measurement circuit coupled to the drain of the second FET and ground, the first leakage measurement circuit including a first measurement point; and a second leakage measurement circuit coupled to the drain of the first FET and ground, the second leakage measurement circuit including a second measurement point.

### RELATED PATENT APPLICATION

This application claims priority to commonly owned U.S. Provisional Patent Application No. 63/710,151, filed on Oct. 22, 2024, which is hereby incorporated by reference.

### FIELD OF THE INVENTION

Detection and/or measurement of current leakage through power transistors.

### BACKGROUND

A commonly used switching semiconductor in a Solid-State Relay (SSR) is the field effect transistor (FET) due to its low power loss when is in conduction. An SSR may be driven by a floating control circuit, as a higher gate potential than drain is required to control an N FET (this is because N-type is more effective in terms of die size related to the switching current). The MOSFET structure implies a (parasitic) body diode (BD) that is artificially created between drain and source. This parasitic body diode makes the transistor an imperfect switch that does not block reverse conduction. This arrangement might affect the circuit function when, for example, the load includes a capacitance that will discharge to the input (through the body diode) when the transistor is turned OFF and the power supply voltage decreases. This may be mitigated by inserting a diode in the circuit block to reverse flow. But this diode must dissipate significant power in forward conduction when the load is significant.

To improve efficiency while preventing back flow, a differential circuit may be implemented using 2 FETs, one in direct and one in reverse conduction. The FETs may be commonly controlled in a simple arrangement. In practice, this topology may leak as the FETs age and especially when thermally stressed.

A drawback of FETs is the associated channel leakage that might increase in time due to ageing and stress conditions and additionally, is highly dependent on the temperature (can increase one hundred-fold over the operation temperature range). For safety applications the leakage represents a risk as the load is not controlled properly. In one example, a SSR may drive an electromechanical relay and the leakage current may be high enough to prevent the SSR from switching the relay off. In another example, where the LOAD has an input capacitor, SSR leakage can slowly charge the capacitor. When a voltage passes a certain threshold, the accumulated energy inside the capacitor can activate the LOAD even if the SSR is OFF.

Existing solutions for evaluating current leakage use complex circuitry with the load placed between the two switches and require access to both the maximally positive and maximally negative potentials of the supply voltage. This may be impractical where the SSR is supposed to float in series with the load.

### SUMMARY

In some examples of the present disclosure, a device is provided comprising a first and a second field effect transistor (FET), each having a source, a drain, and a gate, wherein the source of the first FET and the source of the second FET are both electrically connected to ground; a first leakage measurement circuit coupled to the drain of the second FET and ground, the first leakage measurement circuit including a first measurement point; and a second leakage measurement circuit coupled to the drain of the first FET and ground, the second leakage measurement circuit including a second measurement point. In some examples, the first leakage measurement circuit comprises: a resistor electrically connected between ground and the first measurement point; and a diode with a cathode electrically connected to the drain of the second FET and an anode electrically connected to the first measurement point. In some examples, the first leakage measurement circuit comprises a resistor electrically connected between ground and the first measurement point; and a third FET wherein a source of the third FET is electrically connected to the first measurement point and a drain of the third FET is electrically connected to the drain of the first FET. In some examples, the first leakage measurement circuit comprises a Zener diode with a cathode electrically connected to a gate of the third FET and to a reverse bias voltage source. In some examples, the first leakage measurement circuit comprises: a resistor electrically connected in series with a Zener diode. In some examples, the device comprises a third FET with a drain electrically connected to the drain of the first FET, a source electrically connected to a first end of a bias resistor, and a gate electrically connected to a second end of the bias resistor; and a fourth FET with a drain electrically connected to the drain of the second FET, a source electrically connected to the second end of the bias resistor, and a gate electrically connected to the first end of the bias resistor. In some examples, the device comprises a first control input electrically connected to the first FET gate; and a second control input electrically connected to the second FET gate; wherein the first control input is not electrically connected to the second control input. In some examples, the first FET is thermally coupled to at least a portion of the second measurement circuit. In some examples, the device comprises a temperature sensor for measuring the temperature of the first FET. In some examples, the device includes a controller to, in the following sequence: turn off the first and second FETs; turn on the first FET; measure a voltage at the second voltage point to determine a leakage current through the second FET; and turn on the second FET.

In some examples, a method is provided for controlling a first and a second field effect transistor (FET), each having a source, a drain, and a gate, wherein the source of the first FET and the source of the second FET are both electrically connected to ground; a first resistor electrically is connected between ground and a second measurement point; a first leakage measurement circuit coupled to the drain of the second FET and ground, the first leakage measurement circuit including a first measurement point; a second leakage measurement circuit coupled to the drain of the first FET and ground, the second leakage measurement circuit including a second measurement point; the method comprising: measuring a first voltage of the first measurement point to determine the leakage of the second FET; and measuring a second voltage of the second measurement point to determine the leakage of the first FET. In some examples, the method comprises turning the first FET on, turning the second FET off, and while the first FET is on and the second FET is off, measuring a voltage at the second voltage point to determine a leakage current through the second FET. In some examples, the method comprises turning the second FET on before turning the first FET on. In some examples, the method comprises comparing the leakage current through the second FET to a threshold value to determine an anomalous amount of leakage current. In some examples, the method comprises turning the first FET off; turning the second FET on; while the first FET is off and the second FET is on, measuring a second voltage at the first voltage point to determine a leakage current through the first FET. In some examples, the method comprises turning the first FET on; turning the second FET on; and determining current is flowing from the first FET towards the second FET when the second voltage is zero.

In some examples, a device is provided comprising a first and a second power field effect transistor (FET), each having a source, a drain, and a gate, wherein the source of the first FET and the source of the second FET are both electrically connected to ground; a leak detection means for detecting leakage between the source and drain of at least one of the first power FET and the second power FET, the leak detection means including a first measurement point and a second measurement point; and a controller for monitoring the leak detection means. In some examples, the leak detection means comprises: a first resistor electrically connected between ground and a second measurement point; a first diode with an anode electrically connected to the second measurement point and a cathode electrically connected the second FET drain; a second resistor electrically connected between ground and a first measurement point; and a second diode with an anode electrically connected to the first measurement point and a cathode electrically connected the first FET drain. In some examples, the leak detection means comprises a first enhancement FET and a first depletion FET wherein the drains of the first enhancement FET and the first depletion FET are electrically coupled; and a second enhancement FET and a second depletion FET wherein the drains of the second enhancement FET and the second depletion FET are electrically coupled. In some examples, the gate of the first power FET and the gate of the second power FET are commonly controlled. In some examples, the leak detection means comprises a first diode with an anode electrically connected to ground. In some examples, the first FET is thermally coupled to at least a portion of the leak detection means.

In some examples, a method is provided that includes controlling a circuit, the circuit comprising a first and a second field effect transistor (FET), each FET having a source, a drain, an effective body diode, and a gate, wherein the source of the first FET and the source of the second FET are electrically coupled, a first measurement circuit coupled to the source and drain of the second FET and providing a first measurement point, the first measurement circuit including an impedance, and a second measurement circuit coupled to the source and drain of the first FET and providing a second measurement point, independently controlling a first gate voltage applied to the gate of the first FET and a second gate voltage applied to the gate of the second FET; measuring a first measured voltage at the first measurement point; and measuring a second measured voltage at the second measurement point. In some examples, the method comprises while the voltage from the source to the drain of the second FET is less than a minimum forward voltage of the effective body diode of the second FET, estimating a leakage current through the first FET based at least in part on the first measured voltage. In some examples, the method comprises while the voltage from the source to the drain of the second FET is greater than a minimum forward voltage of the effective body diode of the second FET, sequencing the first gate voltage off then on while concurrently tracking the voltage at the first measurement point to estimate the health of the first FET. In some examples, the method comprises, after receiving a signal to turn off both the first FET and the second FET, determining that the second FET is in reverse conduction at least in part by determining the first measurement voltage is greater than zero, sequencing the second gate voltage off then on while concurrently tracking the second measured voltage to estimate the health of the second FET, and turning off both the first gate voltage and the second gate voltage. In some examples, the method comprises, after receiving a signal to turn on both the first FET and the second FET, turning on the first gate voltage and then determining the first measured voltage is greater than zero volts; sequencing the second gate voltage off then on while concurrently tracking the voltage at the first measurement point to estimate the health of the second FET. In some examples, the method comprises, after receiving a signal to turn on both the first FET and the second FET, turning on the first gate voltage and then determining the first measured voltage is zero volts; then turning on the second gate voltage; then sequencing the first gate voltage off then on while concurrently tracking the voltage at the second measurement point to estimate the health of the first FET.

In some examples, a measurement circuit for a solid-state switch having a first and a second terminal is provided, the measurement circuit comprising a first diode having a cathode electrically connected to the first terminal and an anode electrically connected to a leakage resistor; a second diode having a cathode electrically coupled to the second terminal. In certain examples, a summing resistor is electrically coupled to the anode of the first diode and provides a measurement point. In certain examples, the anode of the first and second diode are electrically coupled. In certain examples, the leakage resistor is grounded. In certain examples, a single control signal controls the gate of each of two FETs in the solid-state switch. In some examples, the anode of each diode is grounded through a leakage resistor where both leakage resistors are of substantially equal resistance. In certain examples, the anode of the first diode is coupled to a first differential resistor to form a first measurement point, the anode of the second diode is coupled to a second differential resistor to form a second measurement point, and a capacitor is electrically connected to the first and the second measurement point, wherein the first and second differential resistor have a substantially equal resistance and the resistance of each differential resistor is greater than about one hundred times the resistance of either leakage resistor.

### Other Examples Include

A topology created to evaluate the main switch leakage (the transistor in direct conduction) in bidirectional way comprises in: two transistors connected back-to-back (one will be in direct and the other one in reverse conduction, depending on momentary current flow), for each the Drain-Source port is in parallel with a resistor serially connected to a diode with the same conduction direction as the FET internal body diode, with the condition that the forward voltage of external diode is lower than the body diode forward voltage, in order to accommodate the sensing resistor maximum sensing voltage swing.

A similar topology where the additional diode is replaced by a transistor, acting as an ideal diode that controlled by a biasing current source. The biasing circuitry generates and artificial leakage that can be eventually, used to validate the health of the auxiliary measurement circuitry.

When the external diode and the transistors presents the same type of thermal drift (both negative or both positive drift), the external diode and the transistor will be thermally coupled to accommodate the minimum required voltage swing on the sensing resistor. In any case, the temperature coefficient for diode shall be lower or equal with the FET body diode to allow expected sensing swing.

The circuit works in dual mode: current sensing when the voltage over body diode is smaller than the minimum forward voltage, and VDS/power loss estimation when the forward voltage across the body diode reaches nominal conditions.

The leakage detection, measurement and FET circuitry health can be determined by a certain control sequence which depends on the current flow, with no interruption of the load circuitry one the load switching is established.

The leakage evaluation is performed every time the SSR is changing its state: OFF to ON and ON to OFF when the FETs runs at different temperatures. The two-points evaluation corroborated with the module temperature measurement during the transitions provides insights on how the leakage value varies with the temperature and determine the leakage impact within the maximum temperature operating range.

During ON state (both FETs turned ON), the voltage evaluation across the leakage monitoring resistors can be used to continuously determine the current flow direction.

### BRIEF DESCRIPTION OF THE FIGURES

FIG. 1 illustrates an example circuit for SSR leak detection and measurement.

FIG. 2 illustrates another example circuit for SSR leak detection and measurement.

FIG. 3 illustrates the operation of an example circuit in the OFF state.

FIG. 4 illustrates the operation of an example circuit in the ON state.

FIG. 5 illustrates the operation of an example circuit under one condition.

FIG. 6 illustrates the operation of an example circuit under a different condition.

FIG. 7 illustrates another example circuit for SSR leak detection and measurement capable of operating at high voltages.

FIG. 8 illustrates another example circuit for SSR leak detection and measurement capable of operating at high voltages.

FIG. 9 illustrates an active load to augment the measurement circuitry, in some examples.

FIG. 10 illustrates the operation of some example circuits in different phases of operation, in some examples.

FIG. 11 illustrates another example circuit for SSR leak detection and measurement.

FIG. 12 illustrates a method of operation of a circuit for SSR leak detection and measurement.

FIG. 13 illustrates another method of operation of a circuit for SSR leak detection and measurement.

FIG. 14 illustrates another example circuit for SSR leak detection and measurement.

FIG. 15 illustrates another example circuit for SSR leak detection and measurement.

FIG. 16 illustrates another example circuit for SSR leak detection and measurement.

### DETAILED DESCRIPTION

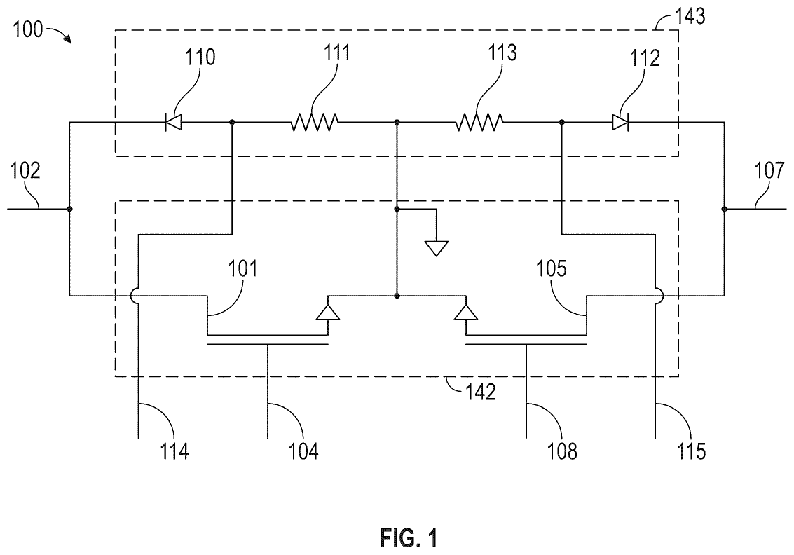

FIG. 1 illustrates an example circuit for SSR leak detection and measurement. Circuit 100 includes power circuitry 142 that may controllably and efficiently pass current to ground and measurement circuitry 143 that may be used to provide measurement information to a controller regarding the operation and/or health of power circuitry 142. Power circuitry 142 may be arranged with terminals 102 and 107 that are selectively electrically connected to allow power to flow through the circuit based on control inputs 104 and 108. Circuit 100 may be a bidirectional circuit that may monitor the leakage during SSR OFF time (based on the FET parasitic body diode characteristics), indicate the circuitry current flow direction, and validate that measurement chain as functional. FET 101 and FET 105 are arranged to selectively pass current from terminal 102 to terminal 107 or from terminal 107 to terminal 102 in reverse flow. Gate input 104 may be used to independently control FET 101. Gate input 108 may be used to independently control FET 105. In some examples, gate input 104 and gate input 108 may be tied together to operate like a traditional solid-state relay yet still include leak detection and measurement capabilities.

Measurement circuitry 143 may include the following elements. Diode 110 and resistor 111 may be arranged to allow measurement of leakage current through FET 105 by generating a voltage measurable at sense line 114 that is proportional to that leakage current. Diode 112 and resistor 113 may be arranged to allow measurement of leakage current through FET 101 by generating voltage measurable at sense line 115 that is proportional to that leakage current. As shown, circuit 100 may be operated with only one of FET 101 and FET 105 in an ON state with current flowing from either terminal 102 or terminal 107 to ground. Measurement circuitry, as that term is used in this disclosure, may refer to the circuitry for measuring leakage current through one FET or the circuitry for measuring leakage current through both FETs, depending on the context.

One example may solve a problem observed in circuits where the load of the solid-state circuit is a traditional electromechanical relay (referred to in this paragraph as “relay”). The current required to turn ON the relay (close the contacts) is typically much higher than the current to maintain the contacts closed. When the FET drain to source leakage, impacted in a negative way by the SSR operating temperature, exceeds a certain level, the relay armatures can remain engaged (temporary or permanently) even when the switch gate control is turned OFF. Another example may solve a problem observed where the complex LOAD had a big reactive component (e.g., an input capacitor or supercapacitor). SSR leakage can slowly charge the capacitor and, when the component's voltage passes a threshold, the reactive component may momentarily power the LOAD with accumulated energy inside the capacitor even if the SSR has been turned off.

Regardless of current flow direction through the SSR of certain examples of the present disclosure, the current will flow through the peer transistor body diode and the voltage drop across the transistor in reversed conduction, will be limited by the forward voltage of the body diode at that specific current and this design enables the possibility of creating a secondary current path with the scope of leakage estimation.

Examples of present disclosure aims to address one or more of the following objectives. Monitor the leakage current of the main switch regardless of the direction of current flow, as the switching elements swaps roles depends on the current flow direction. Identify the current flow direction during the SSR ON state. Identify the biasing direction (port polarity) in OFF state by using an auxiliary μA biasing current circuitry. Design a viable dual port SSR device, for which the leakage parameters can be monitored without need for a maximum and minimum biasing point connection. Minimize the power loss over the switching chain and the detection circuit complexity. Add sensing circuitry diagnose. Additional objectives may be possible with the disclosed examples.

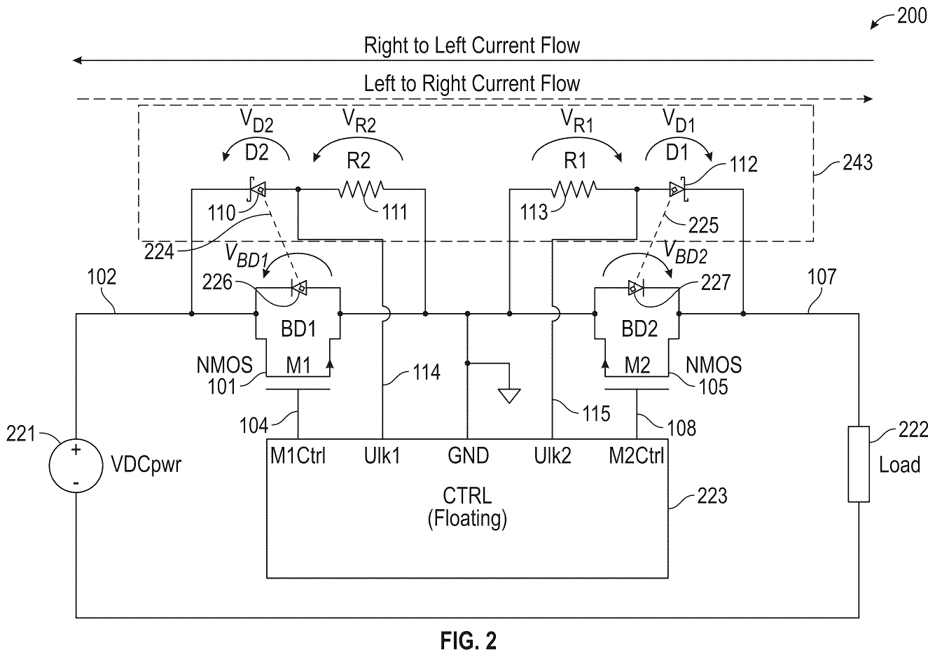

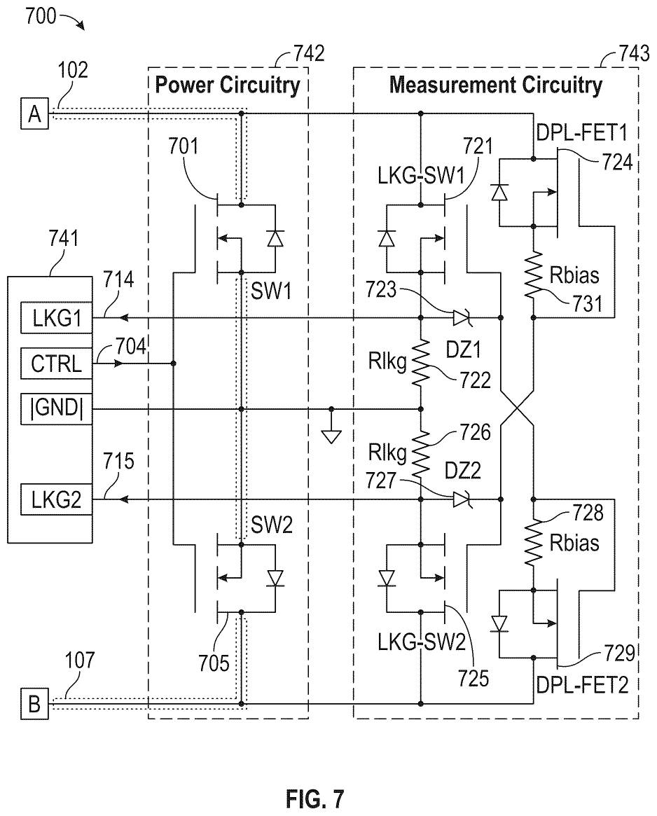

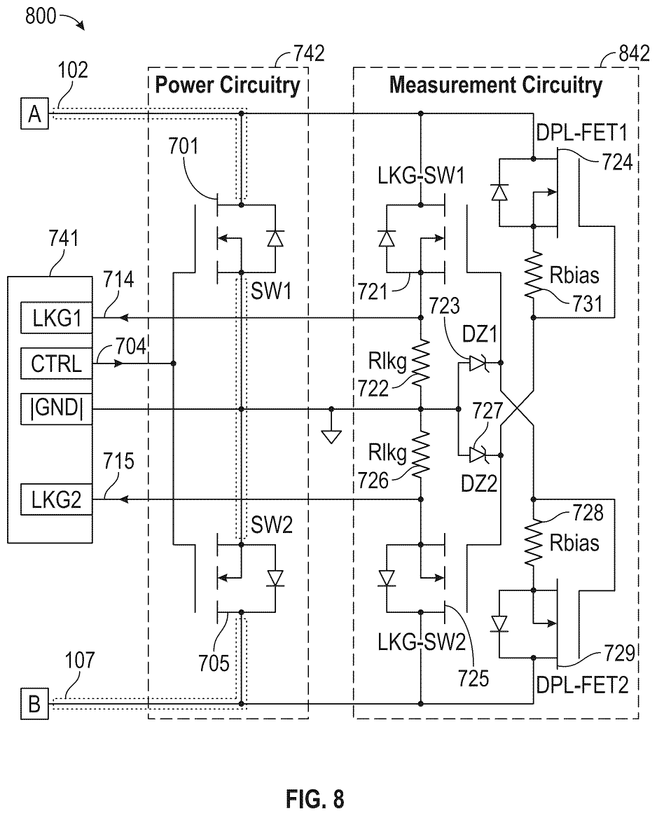

FIG. 2 illustrates an example circuit for SSR leak detection and measurement. Circuit 200 can evaluate the FETs leakage in both directions, validate the functionality of leakage measurement chain, and estimate the current flow direction when the circuitry is switched ON. In addition to the elements described in FIG. 1, circuit 200 includes power supply 221, load 222, and controller 223. Power supply 221 may be an alternating current or direct current power supply. Power supply 221 may be low or high voltage, however commercially available diodes may limit the maximum voltage of power supply 221. Other examples, such as those illustrated in FIG. 7 and FIG. 8 may overcome this limitation. Load 222 may be any desired load. Controller 223 may be a microcontroller with outputs to control gate 104 and gate 108. Controller 223 may include inputs for measuring the voltage at sense lines 114 and 115. In some examples, control 223 may be floating in relation to power supply 221. FET 101 is illustrated with body diode 226, which may be intrinsic to FET 101. FET 105 is illustrated with body diode 227, which may be intrinsic to FET 105. In some examples, heat transfer mechanism 224 may be used to thermally couple diode 110 and FET 101. Heat transfer mechanism 224 may be a thermally conductive plate adhered with thermally conductive cement to diode 110 and FET 101. In some examples, heat transfer mechanism 225 may be used to thermally couple diode 112 and FET 105.

Measurement circuitry 243 (e.g., the arrangement of diodes 110 and 112 along with resistors 111 and 113) relies on the parasitic FETs body diode (e.g., 226 and 227) which works as a voltage limiter: the dropping voltage across the body diode is limited to its forward voltage, VBD, when the transistor is reversed biased. The measurement circuitry comprises, for each transistor, from a pair of resistor with a series diode with same conduction direction as the associated body diode, a circuit that will not create a parasitic leakage path when the main switch is turned OFF (as the series auxiliary diode block the voltage in opposite direction); additionally, the diode can be thermally coupled with the transistor, to ensure for both body diode and auxiliary diode the same forward voltage trend across the entire temperature range.

First, in some examples, controller 223 may independently control gate 104 and gate 108. For example, current flow detection and leakage test circuit validation may require a specific sequence of M1 and M2 control. The added circuitry for leakage evaluation comprises 2 resistors and 2 diodes in series added across the Drain-Source junction of FETs switches. The additional diode conducts in the same direction as the body diode, which will prevent the direct current flow when the FETs are turned OFF.

For the circuit to operate we may ensure that the difference between V_{BD} (the voltage across a body diode) and V_{D} (the voltage across the diode) is greater than 50 mV to 200 mV across the entire temperature operating range. For example, if both the body diode and the additional diode present a negative thermal coefficient, to maintain the dropping voltage difference (across the temperature range) the diodes may need to be thermally coupled. In some examples, it does not really matter if the voltage difference varies with the temperature so long as a minimum margin is maintained across the entire operating range.

For left to right current flow, the leakage will be evaluated by the right side of the circuit composed of FET 105 and body diode 227 (labeled M2 and BD2, respectively), resistor 113 (labeled R1) and diode 112 (labeled D1). For right to left current flow, the leakage will be evaluated by the left side of the circuit composed from FET 101 and body diode 226 (labeled M1 and BD1), resistor 111 (labeled R2) and diode 110 (labeled D2). In other words, the leakage of the transistor in direct conduction (e.g., FET 101) will be evaluated across the reverse conduction branch (e.g., resistor 113 and diode 112).

As the control may be floating, a preferred point to set the reference voltage (GND) is the middle of the structure, as both FET gates require positive biases to be turned ON. For the leakage measurement circuit, the reference may also be set to the middle, so for FET 101 (M1) leakage, the control circuit will measure a span of −(V_{BDMAX}−V_{D}) across resistor 113 (R1) and for FET 105 (M2) leakage, a span of +(V_{BDMAX}−V_{D}) across resistor 111 (R2). By having those voltages limited to a few hundred mV, the measurement for both positive and negative range can be performed by using by virtually any of rail-to-rail input operational amplifier (OPA), in a single power supply configuration, referenced to GND, as they usually support common mode input voltages a few hundred millivolts over the rails.

The functionality of leakage detection circuit may be observed in example scenarios.

In one scenario, both transistors are turned OFF and the current flow is left to right with a leakage on the M1 of 1 mA. The detection resistor may be sized at 100 ohms. We may observe V_{BD2}=0.8V voltage drop across BD2 (at low current). A 0.25V dropping voltage across D1 may result in a 550 mV voltage across R1 which is feasible for current span of maximum 5 mA. So, 1 mA of leakage creates 100 mV across R1 which can be evaluated when both M1 and M2 are turned OFF. In these conditions, the entire current flow (leakage) passes through D1 as BD2 presents high impedance. The voltage drop across the resistors (related to the transistor in reverse conduction) will be a function of leakage current of the transistor in direct conduction.

If M1 is turned ON and M2 turned OFF, the LOAD current will flow through M1 and the body diode BD2; depends on load it will create a dropping voltage between 0.8V and 2V (the range is based on the transistor characteristics). By considering the D1 dropping voltage of 0.35V, the voltage across R1 will be between 450 mV and 1.65V. This voltage can represent a stimulus to check the leakage detector's integrity. If the current flow is left to right, the leakage detection circuitry for M1 comprised from R2 and D2 is reversed biased as the diode D2 blocks the current flow. As result the dropping voltage across R2 will be always 0 (in contrast with the dropping voltage across R1); voltage evaluation across R1 and R2 combined with the state of M1 and M2 makes possible the current flow direction detection and monitoring. This means, the voltage across resistor R1, will be a function of dropping voltage across the 2 diodes (D1 and BD2) and will not be a function of total current flow; the current through the resistor will be (V_{BD2}−V_{D1})/R1.

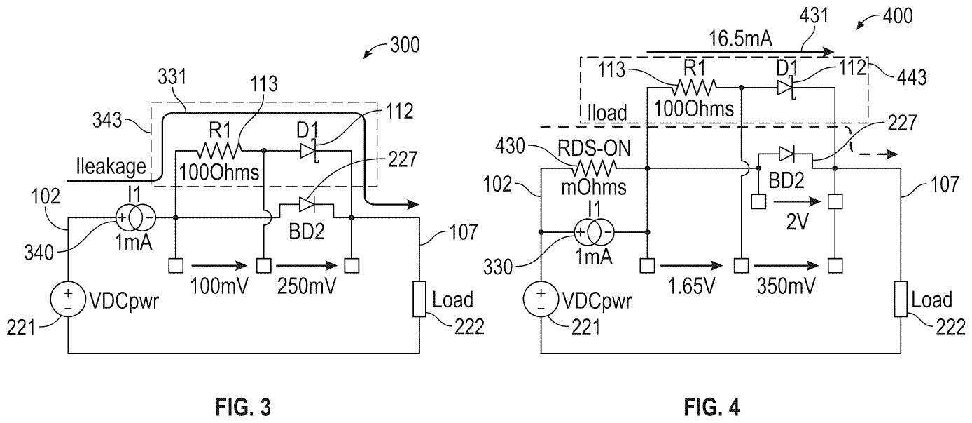

FIG. 3 illustrates the operation of an example circuit in the OFF state. Circuit 300 includes current source 340 representing leakage current 331 of 1 mA through M1 and flowing through measurement circuitry 343.

By assuming the current flow left to right, with an equivalent circuit in OFF state as presented in FIG. 3, with a main switch M1 having a Drain-Source leakage of 1 mA, for a 10002 leakage sensing resistor, if the forward voltage of diode 112 is 250 mV, the total dropping voltage across the body diode 227 (the M2 body diode) will be 350 mV. This means the M2 body diode (BD2) is not in conduction because the current will take the lower impedance path through diode 112 (D1) and resistor 113 (R1) (as the assumed body diode forward voltage is around 2V). The difference between body diode and auxiliary diode forward voltage basically accommodates a maximum leakage swing range. The voltage drop across the resistor (related to the transistor in reverse conduction) will be a function of leakage current (R1*I_{leakage}) of the transistor in direct conduction.

FIG. 4 illustrates the operation of an example circuit in the ON state. Circuit 400 also includes resistor 430 (representing the impedance of I_{load} through M1 in the ON state) and current 432 through resistor 113 (R1) and diode 112 (D1). Circuit 400 also indicates leakage current of 16.5 mA through measurement circuitry 443, which includes resistor 113 and diode 112.

If FET 101 (M1) is in ON state, and FET 105 (M2) in OFF state (with M1, M2 independently controlled—see FIG. 4), most of the load nominal current will flow through body diode 227, and the voltage will be limited to body diode 227 forward voltage, and the voltage drop over resistor 113 (R1) will be the difference between the forward drop over body diode and auxiliary diode (V_{FVBD2}−V_{FVD1}). If the M2 is ON as well, the dropping voltage over R1 will be the difference (R_{DSM2}*Iₙₒₘᵢₙₐₗ−V_{FVD1}). The voltage drop across sensing resistors (related to the transistor in reverse conduction) will be the difference between Drain-Source voltage (V_{FVBD2} or R_{DSM2}*Iₙₒₘᵢₙₐₗ depends on M2 state) and D1 forward voltage.

In both cases as the diode D2 is blocked for a left to right current flow, the dropping voltage across R2 will be always 0. A zero and non-zero value over R1 and R2 is indication of momentary current flow direction when the SSR is ON or in OFF state when the main switch had leakage. If no leakage or the load circuitry is interrupted, both dropping voltages across R1 and R2 are 0V.

By limiting the voltage magnitude, across R1 and R2, to a few hundred mV, in negative range (related to GND as midpoint between the resistors), the leakage can be measured by a common rail-to-rail operational amplifier (OPA), in inverting mode and unipolar power supply configuration, as most of them support a common mode input voltages over the rails greater within a few hundreds of mV, so the maximum swing (even negative) can be accommodated.

By managing independently the M1 and M2 control sequence during circuit switching (OFF to ON and ON to OFF), it is possible to evaluate the SSR leakage in OFF state (at different temperatures depends on the transition type OFF to ON or ON to OFF as we can assume dissipated heat during ON state), identify and monitor the current flow direction, and check the health of the leakage detection chain circuitry.

In the OFF state (M1 and M2 OFF) there is virtually no current flow through the structure (except for the leakage), so, the right sequence of turning ON M1 and M2 might be unknown. One approach is to make a guess and check the results.

If we guess a current flow from left to right, we decide to switch first M1, followed by M2 as can be seen in the picture below. During the step “1”, both transistors are OFF. The dropping voltage across the resistor associated with the direct conduction transistor M1 will be 0V (see the green graph) as the D2 diode is blocked and across the resistor for the transistor in reversed conduction we can measure the leakage (e.g., line 503 in FIG.).

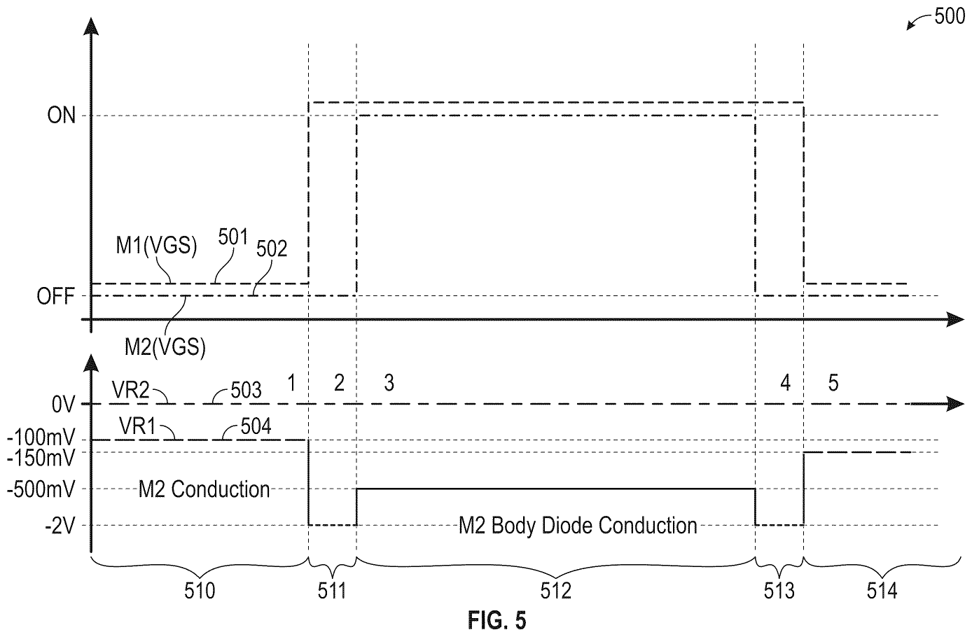

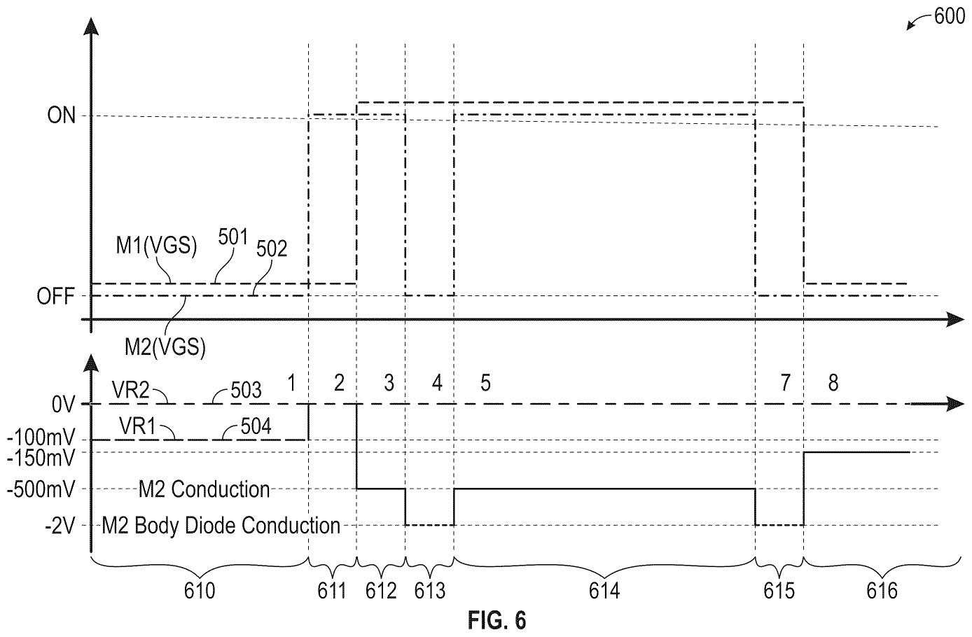

During OFF/ON transition at environment temperature, and then during ON/OFF transition at operating temperature, through a smart control sequence (as presented on FIG. 5 and FIG. 6), it is possible to: measure the leakage, when both transistors are OFF, evaluate the transistors health, by comparing the body diode dropping voltage versus RDSON voltage, when main switch is ON and the reverse conductive switch is sequentially OFF then ON, and continuously detecting the current flow direction when the main switch is ON.

If there is no leakage, VR1 will be 0, in our case is 1 mA which corresponds for a dropping voltage of 100 mV across R1. So, by evaluating the dropping voltages over R1 and R2 (in OFF state) is possible to estimate the leakage amplitude and the current flow when is one of the transistor leaks. If the circuit is healthy, it will be no leakage. If our assumption was correct, on step “2” with M2 OFF and M1 ON, the current will close through the load and M2 body diode, so the voltage evaluated will reflect the dropping voltage over the body diode BD2 (e.g., during time period 511 in FIG. 5). As the instantaneous power dissipation on the body diode is considerable, the next step will be to turn on M2 so, a big part of the body diode current is diverted through M2 channel in reversed conduction. Because the overall M2 DS impedance decrease, the reflected dropping voltage across R1 will decrease as well. When both transistors (M1 and M2) are ON, the voltage combination across R1 and R2 will indicate continuously the current flow direction through the structure as will help in taking the correct turn OFF sequence when required.

If there is no leakage when both transistors main and auxiliary measurement switches are turned OFF, the biasing direction cannot be predicted. By contrast, if the main switch had leakage, the resistor across the auxiliary measurement switch will detect the leakage and the current flow will be in the same direction as its related body diode.

FIG. 5 illustrates the operation of an example circuit under one guess as to current flow. Timing diagram 500 illustrates at line 501 the state of FET 101 (M1), at line 502 the state of FET 105 (M2), at line 503 the voltage across R2 (VR2) measured at sense line 114, and at line 504 the voltage across R1 (VR1) measured at sense line 115. Timing diagram 500 includes time periods 510-514.

During the control sequence, if the circuit correctly guesses the current flow is left to right (see FIG. 5), the circuit can detect:
Step 1: Leakage through the structure (in both directions—depends on biasing)
Step 2: Body diode dropping voltage evaluation (as a FET health check measure)
Step 3: Voltage dropping in reverse conduction (as a FET health check measure and as dynamic current flow detection)

The circuit determine a leakage increase in M1, on the secondary measurement, right after it turns the structure OFF (in comparison with OFF to ON transition) as the transistor die temperature develops during the ON time under load conditions. If the temperature is monitored, the correlation with the leakage value may be used to predict the impact to system safety within the maximum operating temperature range. For example, 2-point interpolation may be used to predict leakage at any temperature within the operating range.

FIG. 6 illustrates the operation of an example circuit under the opposite guess as to current flow. Timing diagram 600 illustrates at line 501 the state of FET 101 (M1), at line 502 the state of FET 105 (M2), at line 503 the voltage across R2 (VR2) measured at sense line 114, and at line 504 the voltage across R1 (VR1) measured at sense line 115. Timing diagram 600 includes time periods 610-616.

If the guess regarding the current flow is wrong (i.e., if the current flow is right to left), the circuit first switches M2 and then switches M1 (as can be seen in FIG. 6). If M1 and M2 present no leakage, both VR1 and VR2 are 0V because, once M1 is switched, M2 remains in reverse conduction and the circuit will remain open. Because FET impedance is low, the voltage across R1 will be 0V even when M1 presents leakage.

If the circuit guesses the current flow direction incorrectly (see FIG. 6), the circuit may perform several additional steps:
Step1: Both transistors are OFF; a negative voltage across a resistor will indicate leakage, if no leakage both voltages across both resistors are 0V.
Step2: The circuit turns M2 ON with the guess that M2 is the main switch allowing current to flow through the load to ground (e.g., right to left in FIG. 2). If the voltage across M1 remains at or goes to 0V, then the circuit determines it turned on the wrong transistor; but the circuit leaves M2 ON to avoid interrupting the flow of current.
Step3: The circuit turns ON M1, the main switch (we know that after the second step), and this will reflect on the secondary switch sensing resistor the voltage drop over M2 in reverse conduction as now both M1 and M2 are turned ON.
Step4: As the sequence was wrong, the circuit momentarily turns OFF M2 and samples the voltage of M2 FET body diode forward conduction (this will not cause a load interruption because the secondary transistor is either in reverse conduction and the primary transistor has its body diode in forward conduction).
Step5: The circuit turns M2 ON to minimize the power loss across M2.

If during step “2” both voltages across the resistors are 0, an extra step may be performed by the circuit. In the adjusted sequence: the transistor M1 will be maintained in conduction, then M2 will be turned ON. Once M1 is turned ON, the voltage over R1 will indicate the current flow, and the circuit may safely turn M1 back OFF (step 4) without load disconnection as the circuit will be established through the body diode. Then the circuit may turn M2 back ON (step 5). In this way all functionality related parameters can be fully evaluated: OFF state leakage during step 1, body diode conduction during step 4 and M2 conduction during step 5.

When both transistors are in ON state, a dropping voltage different that 0V over one of resistor will indicate the current flow direction: the associated transistor for which the voltage is not 0V is the one in reverse conduction. 0V on both, can indicate a disconnected load or other circuit interruption.

The ON to OFF right sequence may be established after as it is indicated by the dropping voltage over sensing resistor of the secondary switch. The primary switch sensing will be 0V because the series diode blocks the current flow.

As previously explained, in some examples it is important to ensure that the selected additional diode had a lower forward voltage than the parasitic transistor body diode and the forward voltage difference is consistently maintained across the entire operating temperature range.

This might create a limitation in some cases because if the diode is Schottky, the maximum reverse voltage for the parts available today on the market is 200V.

The circuits in FIG. 7 and FIG. 8 propose alternative solutions, which replace the diode with a MOSFET controlled by a biasing current source.

FIG. 7 illustrates an example circuit for SSR leak detection and measurement capable of operating at high voltages. Circuit 700 includes controller 741, power circuitry 742, and measurement circuitry 743. Controller 741 may be a microcontroller that includes a processor, working memory, non-transitory computer readable memory for storing instructions to be executed on the processor, at least one output for controlling one or both FET in power circuitry 742, and two inputs for measuring voltages at test points within measurement circuitry 743.

Power circuitry 742 may include FET 701 and FET 705. FET 701 and FET 705 may be enhancement mode MOSFETs. FET 701 may be arranged to controllably connect power tap 102 to ground and, when off, an internal body diode of FET 701 is reversed biased. Similarly, FET 705 may be arranged to controllably connect power tap 107 to ground and, when off, an internal body diode of FET 705 is reversed biased.

Measurement circuitry 743 may include an arrangement of components to perform one or all of the functions performed by measurement circuitry 143 (FIG. 1) but may operate at substantially greater voltages. Measurement circuitry 743 includes FETs 721 and 725 (which may be enhancement mode MOSFETs), diodes 723 and 727 (which may be Zener diodes), FETs 724 and 729 (which may be depletion mode MOSFETs), and resistors 723, 726, 728, and 731. To limit the gate to source voltage, the biasing current through the depletion MOSFETs effective current generator will flow through the Zener diodes. FETs 721 and 725 (also labeled LKG-SW1 and LKG-SW2, respectively) each emulates an ideal diode when the body diode is in forward conduction. Measurement circuitry 743 is arranged in two branches. The first branch includes FETs 721 and 729, diode 723, and resistors 722 and 728. The second branch includes FETs 725 and 724, diode 727, and resistors 726 and 731. FET 721 is biased by the effective current generator of FET 729 and resistor 728 and FET 725 is biased by the effective current generator of FET 724 and resistor 731. The branch of forward conduction is determined by the biasing polarity across taps 102 and 107 (also labeled points A and B, respectively). The two branches (direct and reversed) are biased with small currents in μA range that overlap over the main switch leaking; the need for biasing creates a difference between the diode and ideal diode topology.

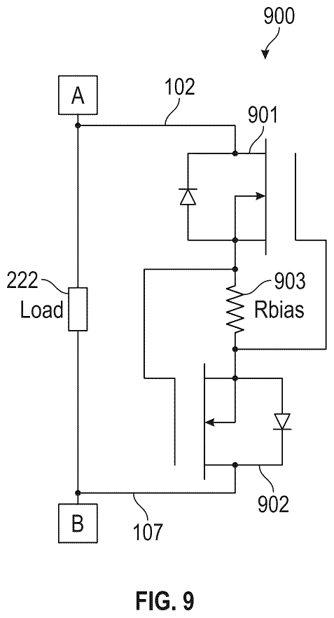

FIG. 8 illustrates another example circuit for SSR leak detection and measurement capable of operating at high voltages. Here, the biasing current is added over the leakage current as a measurement component; this means, during OFF time the biasing circuitry can be measured and used as test for the leakage processing chain. Comparing with diode version (e.g., FIG. 2), the new topology adds an artificial leakage to the switch. As the biasing magnitude can be adjusted, this leakage is chosen in a way that will not affect the load safe state, or eventually, an active load can be placed in parallel with the load to compensate this biasing current as presented in FIG. 9.

The ultra-wide range current biasing of FIGS. 7 and 8 may be implemented with depletion MOSFETs 724 and 729 (also labeled DPL-FET1 and DPL-FET2, respectively) and resistors 728 and 731 (also labeled Rbias). Depending on the current flow direction, either one or the other branch of measurement circuitry 824 may be active.

When the SSR (e.g., power circuitry 742) is turned ON, the secondary switch (in reverse conduction) measurement circuitry measures the dropping voltage across the transistor as an indication of the current flow sense or power dissipation. The other branch will always measure 0V.

FIG. 9 illustrates an active load to augment the measurement circuitry, in some examples. Circuit 900 includes FETs 901 and 902 (which may be depletion mode FETs) and resistor 903. This active load may be used to compensate for biasing current passed by the measurement circuitry.

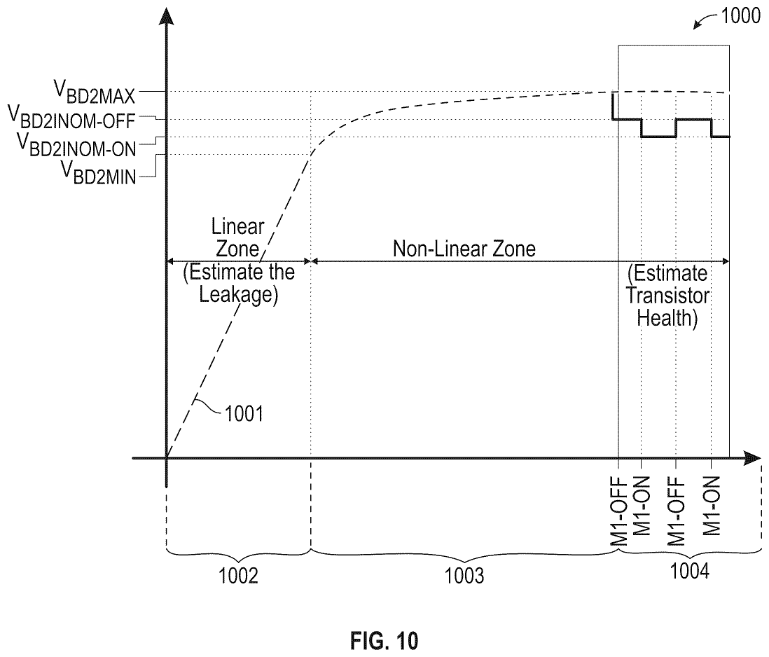

FIG. 10 illustrates the operation of some example circuits in different states of operation, in some examples. Graph 1000 illustrates the drain to source voltage of FET 105 (M2) graphed as curve 1001 as a function of current flowing through the reverse biased transistor circuitry of FET 101 (M1) on the X-axis. Voltage thresholds are labeled along the Y-axis and include: V_{BD2MAX}, V_{BD2INOM-OFF}, V_{BD2INOM-ON}, and V_{BD2MIN}. V_{BD2MIN} is the minimum forward voltage when the body diode starts conducting. V_{BD2MAX} is the maximum forward voltage for which the transistor forward voltage will remain quasi-constant. V_{BD2INOM-OFF} and V_{BD2INOM-ON} represent the voltage drop that occurs when body diode 227 (BD2) is forward biased and FET 105 (M2) is OFF or ON (with the channel in reverse conduction), respectively.

Graph 1000 illustrates three states of operation. In state 1002, the voltage is in a linear zone that can be used to measure current leakage through FET 101 (M1). In this state of operation, the voltage is linearly correlated to the current flowing through resistor—113 (R1) as the voltage is not sufficient to forward bias body diode 227 (BD2). Thus, body diode 227 will not conduct and all current will flow through resistor 113 (R1) and diode 112 (D1). As a result, the current leakage can be calculated as the voltage at test point 115—the drain to source voltage minus the drop across diode 112 (D1)—divided by the resistance of resistor 113 (R1, e.g., 100 Ohms).

In state 1003, the drain to source voltage exceeds the parasitic body diode minimum forward voltage (but is less than the maximum forward voltage) thus allowing current to flow through body diode 227 (BD2). This alternate current path renders curve 1001 non-linear during this state. For a diode, e.g., BD2, in full conduction, the forward voltage is logarithmic and depends on current and temperature. As a result, the voltage drop across resistor 113 (R1) is “tempered” to a logarithmic function.

In state 1004, FET 105 (M1) may be cycled between ON and OFF to estimate the health of the transistor. If FET 105 is healthy, the voltage drop across FET 105 will follow a pattern resembling that shown in state 1004.

This figure has been described in reference to left to right current flow, but applies equally to right to left current flow where leakage of FET 105 may be measured by current flowing through resistor 111 and the health of FET 101 may be measured.

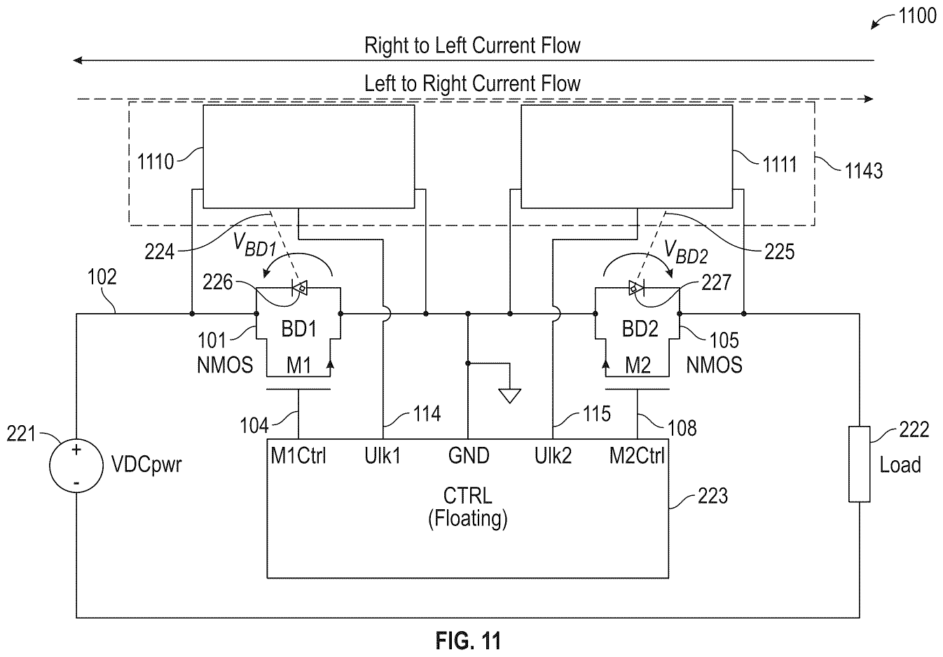

FIG. 11 illustrates another example circuit for SSR leak detection and measurement. Circuit 1100 generally matches circuit 200 of FIG. 2 but incorporates alternative current measurement circuitry. Circuit 111 includes current measurement circuits 1110 and 1111. This topology may comprise a transistor (e.g., FET 101) biased in reverse direction in parallel with a measurement circuit (e.g., measurement circuit 1111) that may present an AC or DC impedance to ensure a dropping voltage across the measurement circuit that is maintained while that dropping voltage rises above the minimum body diode forward voltage of a FET (e.g., FET 105). This arrangement may allow for a maximum measurable leakage current. This arrangement may also allow for transistor health estimation (when operating at nominal current) as a measure of the power loss/dropping voltage ratio between the state of the FET is off (only the body diode is conducting) or ON (when the transistor channel is in reverse conduction and the current flows through both the body diode and the channel).

In some examples, measurement circuit 1110 may include a resistor to generate a measurable voltage using Ohm's Law (i=V/R). In an example, measurement circuit 1110 may be implemented with a synchronous demodulator and a high voltage input capacitor. In this example, the capacitor will block the DC voltage when the transistor is in direct conduction. To modulate the leakage current (in order to pass the demodulator input chain), the reversed biased transistor can be turned on and off at a certain frequency. The demodulator input impedance (adjusted to match the measurement range) can act as a current to voltage converter when operating in a leakage measurement mode. Other current sensing approaches may be employed. Measurement circuit 1111 may be constructed of the same components as measurement circuit 1111.

A core function of the power circuitry is to act as a solid-state relay. The two transistors connected source to source ensure the conduction control in both directions. Depending on the bias sense (current direction), one transistor will always conduct (regardless of the gate control), and the other will block the current flow or it will be in conduction. This structure is functions like a mechanical switch.

The switch is turned ON or OFF, depending on the load needs. Once the structure is turned ON, the control circuit test protocols (e.g., testing for transistor health, current leakage, etc.) should not interfere with the load state. In most examples, even a temporary interruption of the current flow as a result of testing will be totally forbidden. In some applications, a short interruption of current flow can create a dangerous voltage overshoot. In some applications, allowing or increasing current through the power circuitry during testing may result in dangerous conditions. In some applications, the power circuitry may activate a higher voltage relay or energize an electric vehicle drive train.

The initial biasing of the power circuitry may be unknown and that biasing further determines the current direction through the structure. Thus, it is important to carefully design the turn ON and OFF sequence for the two power transistors (e.g., FET 101 and FET 105) that allow safe testing at both ON/OFF and OFF/ON transitions without interruption.

If the power circuitry state is ON, a small fraction of the nominal current is diverted through the measurement circuitry (e.g., R1/D1) and over the sensing resistor (e.g., R1) such that measurement at test point 115 will observe a dropping voltage. However, this voltage is present only for the branch in reverse conduction, because the blocking diode will stop the flow for the transistor in direct conduction. Thus, in this example, no voltage drop will be sensed at test point 114 because no current is flowing through (e.g., R2/D2). In some examples, power supply 221 may be an alternating current supply and a voltage test may indicate 0V along both branches of the measurement circuitry. In these examples, it may be prudent to sample voltages at test points 114 and 115 multiple times to ensure the power circuitry is biased before proceeding and may ensure the power circuitry is biased to a specified degree before proceeding.

Based on that fact the branch of measurement circuitry with a test voltage greater than 0V (both voltages are sampled right prior turn ON/OFF action) is related to the branch in reverse conduction, its associated transistor can be turned ON and OFF, for testing proposes without interrupting the load circuit (the load can see small variation of biasing but without cutting the power through testing). After the health testing is done, the current can be turned OFF by turning OFF the main transistor that is in direct conduction. To test before a turn OFF event, a minimum of 2 steps are necessary (first for testing then to turning OFF).

If the power circuitry state is OFF, additional steps may be needed before testing may be performed. In this state, there should be no current flow through the power circuitry. If there is no leakage, on both branches of the measurement circuitry the sensed voltages are 0V. Without additional information there is no logical way to determine the bias across the power circuitry. Instead, the control circuitry may hypothesize the bias is in one direction and confirm or reject that hypothesis. In other words, guess and check to see if the guess is correct. The hypothesis/guess may be random or may always pick one bias direction. If the hypothesis is correct, the FET turned ON will be in direct conduction and the health check may take two steps to turn ON then OFF then FET in reverse conduction.

If the hypothesis is incorrect, the FET turned ON will be in reverse conduction and the health check may take four steps. In this case, the load is still disconnected and the measurement voltage across the resistor related to the reverse conduction transistor will go to 0V (with or without leakage current). Then, the other FET be turned ON to connect the load. To test the FET health, the control circuit momentarily turns OFF and ON the first transistor (which we know now is in reverse conduction). This will not disconnect the load but will accomplish the required test.

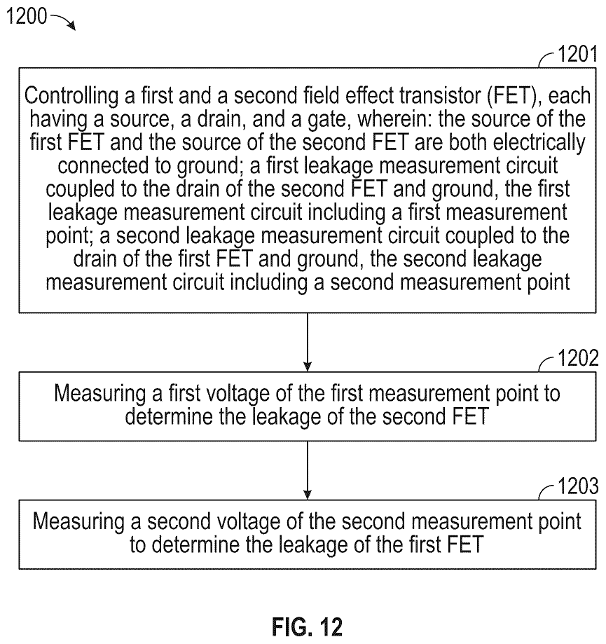

FIG. 12 illustrates a method of operation of a circuit for SSR leak detection and measurement. At block 1201, the method begins by controlling a first and a second field effect transistor (FET), each having a source, a drain, and a gate, wherein: the source of the first FET and the source of the second FET are both electrically connected to ground; a first leakage measurement circuit coupled to the drain of the second FET and ground, the first leakage measurement circuit including a first measurement point; a second leakage measurement circuit coupled to the drain of the first FET and ground, the second leakage measurement circuit including a second measurement point. At block 1202, the method continues by measuring a first voltage of the first measurement point to determine the leakage of the second FET. At block 1203, the method continues by measuring a second voltage of the second measurement point to determine the leakage of the first FET.

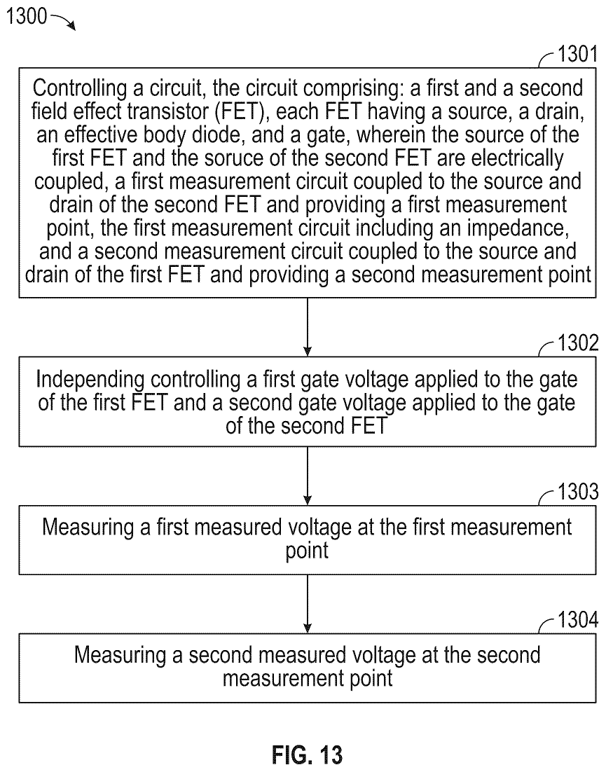

FIG. 13 illustrates another method of operation of a circuit for SSR leak detection and measurement. At block 1301, the method begins by controlling a circuit, the circuit comprising: a first and a second field effect transistor (FET), each FET having a source, a drain, an effective body diode, and a gate, wherein the source of the first FET and the source of the second FET are electrically coupled, a first measurement circuit coupled to the source and drain of the second FET and providing a first measurement point, the first measurement circuit including an impedance, and a second measurement circuit coupled to the source and drain of the first FET and providing a second measurement point. The method continues at block 1302 by independently controlling a first gate voltage applied to the gate of the first FET and a second gate voltage applied to the gate of the second FET. At block 1303, the method continues by measuring a first measured voltage at the first measurement point. At block 1304, the method continues by measuring a second measured voltage at the second measurement point.

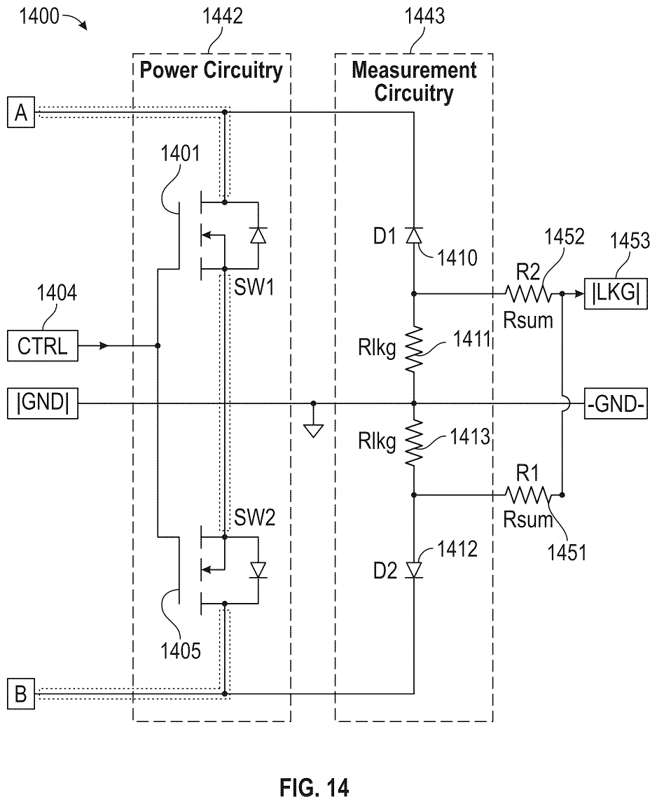

FIG. 14 illustrates another example circuit for SSR leak detection and measurement. Power circuitry 1442 includes FET 1401 and FET 1405 with common control 1404. Measurement circuitry 1443 includes diode 1410, resistor 1411, resistor 1413, and diode 1412. In this example, the two measurement points are summed with resistor 1451 and resistor 1452 to form a common measurement point 1453.

The two points that collect the leakage may be summed through the resistors 1451 (R1) and 1452 (R2). In some examples, R1 is sized equal to R2 and the resistance of R1 is substantially greater than one hundred times the resistance of R_{1kg}. In one example, R_{1kg} may be 51Ω and R1=R2=100 kΩ. In this arrangement, the summing output (measured relative to ground) will be always modulo voltage of the leakage divided by 2, regardless of the direction of the flowing current. The circuit will report the leakage, if one exists, as a negative voltage. This may be helpful for AC applications where the current flow can change; by having always the leakage as modulo, the detection circuit becomes easier to implement.

The functionality is as follows: the dropping voltage on one of the leakage detection resistors (i.e., resistor 1411 or resistor 1413) is always 0V because either D1 or D2 is reversed biased depending on the current flow direction. As a result, R1 and R2 will look like a voltage divider. If R1=R2=R, giving the symmetry of the circuit, the division will be always 2. So, the output is always negative and divided by 2.

The output is:

$$V = - \frac{\vert {I}_{lkg} \cdot {R}_{lkg} \vert}{2} , ( for R 1 = R 2 = R ) .$$

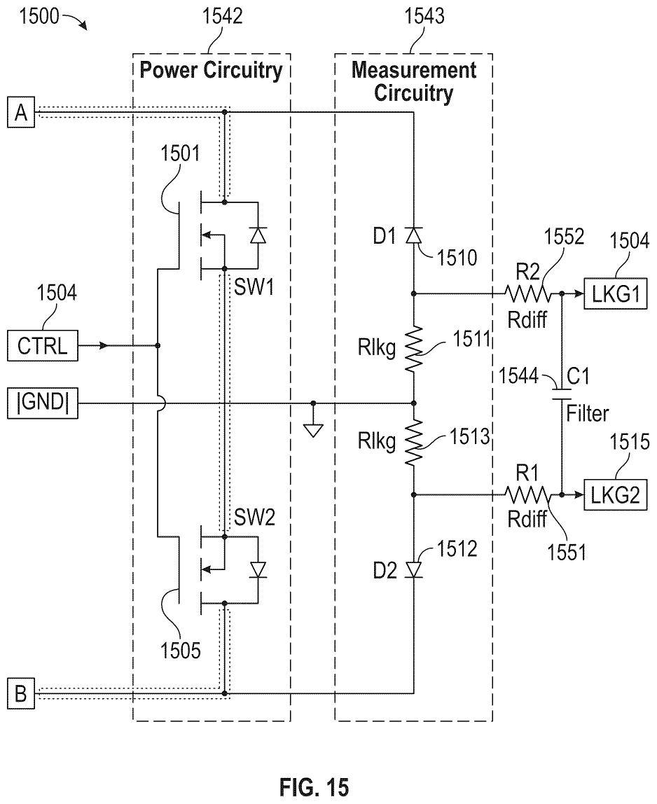

FIG. 15 illustrates another example circuit for SSR leak detection and measurement. Power circuitry 1542 includes FET 1501 and FET 1505 with common control 1504. Measurement circuitry 1543 includes diode 1510, resistor 1511, resistor 1513, and diode 1512. In this example, the measurement points at resistors 1511 and 1513 are fed through additional resistors (resistors 1551 and 1552) which are coupled to filtering capacitor 1544 to form measurement points 1504 and 1515. In this example, the leakage voltage is evaluated between the two points as a differential voltage. This may help measure the leakage using a configuration that allows filtering and common-mode voltage, when the ground point is floating.

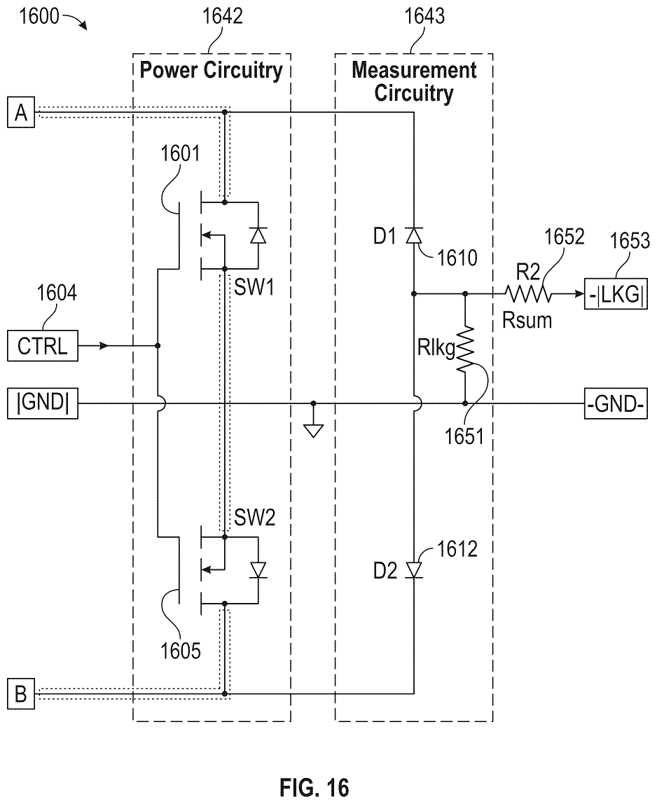

FIG. 16 illustrates another example circuit for SSR leak detection and measurement. Circuit 1600 is a further simplification of the measurement circuitry illustrated in FIG. 14. In this example, power circuitry 1642 includes FET 1601 and FET 1605 with common control 1604. Measurement circuitry 1643 includes diode 1610 and diode 1612 coupled to a single leakage resistor 1651. An additional resistor 1652 operates as a summing resistor to generate a voltage at common measurement point 1653. In this example, the output is: V=−|I_{llkg}·R_{lkg}.

Although examples have been described above, other variations and examples may be made from this disclosure without departing from the spirit and scope of these examples.

We claim:

1. A device comprising:
a first and a second field effect transistor (FET), each having a source, a drain, and a gate, wherein the source of the first FET and the source of the second FET are both electrically connected to ground;
a first leakage measurement circuit coupled to the drain of the second FET and ground, the first leakage measurement circuit including a first measurement point; and
a second leakage measurement circuit coupled to the drain of the first FET and ground, the second leakage measurement circuit including a second measurement point.

2. The device of claim 1, wherein the first leakage measurement circuit comprises:
a resistor electrically connected between ground and the first measurement point; and
a diode with a cathode electrically connected to the drain of the second FET and an anode electrically connected to the first measurement point.

3. The device of claim 1, wherein the first leakage measurement circuit comprises:
a resistor electrically connected between ground and the first measurement point; and
a third FET wherein a source of the third FET is electrically connected to the first measurement point and a drain of the third FET is electrically connected to the drain of the first FET.

4. The device of claim 3, wherein the first leakage measurement circuit comprises:
a Zener diode with a cathode electrically connected to a gate of the third FET and to a reverse bias voltage source.

5. The device of claim 1, wherein the first leakage measurement circuit comprises:
a resistor electrically connected in series with a Zener diode.

6. The device of claim 1, comprising:
a third FET with a drain electrically connected to the drain of the first FET, a source electrically connected to a first end of a bias resistor, and a gate electrically connected to a second end of the bias resistor; and
a fourth FET with a drain electrically connected to the drain of the second FET, a source electrically connected to the second end of the bias resistor, and a gate electrically connected to the first end of the bias resistor.

7. The device of claim 1, comprising:
a first control input electrically connected to the first FET gate; and
a second control input electrically connected to the second FET gate;
wherein the first control input is not electrically connected to the second control input.

8. The device of claim 1, wherein the first FET is thermally coupled to at least a portion of the second measurement circuit.

9. The device of claim 1, comprising a temperature sensor for measuring the temperature of the first FET.

10. The device of claim 1, comprising a controller to, in the following sequence:
turn off the first and second FETs;
turn on the first FET;
measure a voltage at the second voltage point to determine a leakage current through the second FET; and
turn on the second FET.

11. A method comprising:
controlling a first and a second field effect transistor (FET), each having a source, a drain, and a gate, wherein:
the source of the first FET and the source of the second FET are both electrically connected to ground;
a first resistor electrically is connected between ground and a second measurement point;
a first leakage measurement circuit coupled to the drain of the second FET and ground, the first leakage measurement circuit including a first measurement point;
a second leakage measurement circuit coupled to the drain of the first FET and ground, the second leakage measurement circuit including a second measurement point;
measuring a first voltage of the first measurement point to determine the leakage of the second FET; and
measuring a second voltage of the second measurement point to determine the leakage of the first FET.

12. The method of claim 11, comprising:
turning the first FET on,
turning the second FET off, and
while the first FET is on and the second FET is off, measuring a voltage at the second voltage point to determine a leakage current through the second FET.

13. The method of claim 12, comprising:
turning the second FET on before turning the first FET on.

14. The method of claim 11, comprising:
comparing the leakage current through the second FET to a threshold value to determine an anomalous amount of leakage current.

15. The method of claim 11, comprising:
turning the first FET off;
turning the second FET on;
while the first FET is off and the second FET is on, measuring a second voltage at the first voltage point to determine a leakage current through the first FET.

16. The method of claim 11, comprising:
turning the first FET on;
turning the second FET on; and
determining current is flowing from the first FET towards the second FET when the second voltage is zero.

17. A device comprising:
a first and a second power field effect transistor (FET), each having a source, a drain, and a gate, wherein the source of the first FET and the source of the second FET are both electrically connected to ground;
a leak detection means for detecting leakage between the source and drain of at least one of the first power FET and the second power FET, the leak detection means including a first measurement point and a second measurement point; and
a controller for monitoring the leak detection means.

18. The device of claim 17, wherein the leak detection means comprises:
a first resistor electrically connected between ground and a second measurement point;
a first diode with an anode electrically connected to the second measurement point and a cathode electrically connected to the second FET drain;
a second resistor electrically connected between ground and a first measurement point; and
a second diode with an anode electrically connected to the first measurement point and a cathode electrically connected to the first FET drain.

19. The device of claim 17, wherein the leak detection means comprises:
a first enhancement FET and a first depletion FET wherein the drains of the first enhancement FET and the first depletion FET are electrically coupled; and
a second enhancement FET and a second depletion FET wherein the drains of the second enhancement FET and the second depletion FET are electrically coupled.

20. The device of claim 17, wherein the gate of the first power FET and the gate of the second power FET are commonly controlled.

21. The device of claim 17, wherein the leak detection means comprises a first diode with an anode electrically connected to ground.

22. The device of claim 17, wherein the first FET is thermally coupled to at least a portion of the leak detection means.

23. A method comprising:
controlling a circuit, the circuit comprising:
a first and a second field effect transistor (FET), each FET having a source, a drain, an effective body diode, and a gate, wherein the source of the first FET and the source of the second FET are electrically coupled,
a first measurement circuit coupled to the source and drain of the second FET and providing a first measurement point, the first measurement circuit including an impedance, and
a second measurement circuit coupled to the source and drain of the first FET and providing a second measurement point,
independently controlling a first gate voltage applied to the gate of the first FET and a second gate voltage applied to the gate of the second FET;
measuring a first measured voltage at the first measurement point; and
measuring a second measured voltage at the second measurement point.

24. The method of claim 23, comprising, while the voltage from the source to the drain of the second FET is less than a minimum forward voltage of the effective body diode of the second FET, estimating a leakage current through the first FET based at least in part on the first measured voltage.

25. The method of claim 23, comprising, while the voltage from the source to the drain of the second FET is greater than a minimum forward voltage of the effective body diode of the second FET, sequencing the first gate voltage off then on while concurrently tracking the voltage at the first measurement point to estimate the health of the first FET.

26. The method of claim 23, comprising, after receiving a signal to turn off both the first FET and the second FET:
determining that the second FET is in reverse conduction at least in part by determining the first measurement voltage is greater than zero,
sequencing the second gate voltage off then on while concurrently tracking the second measured voltage to estimate the health of the second FET, and
turning off both the first gate voltage and the second gate voltage.

27. The method of claim 23, comprising, after receiving a signal to turn on both the first FET and the second FET:
turning on the first gate voltage and then determining the first measured voltage is greater than zero volts;
sequencing the second gate voltage off then on while concurrently tracking the voltage at the first measurement point to estimate the health of the second FET.

28. The method of claim 23, comprising, after receiving a signal to turn on both the first FET and the second FET:
turning on the first gate voltage and then determining the first measured voltage is zero volts;
then turning on the second gate voltage;
then sequencing the first gate voltage off then on while concurrently tracking the voltage at the second measurement point to estimate the health of the first FET.
